(19) United States
(12) Patent Application Publication
(10) Pub. No.: US 2023/0100972 A1
(43) Pub. Date: Mar. 30, 2023

(54) Method for producing a coating of a base body and functional element having a base body with a coating

(71) Applicant: Technische Universität Darmstadt, Darmstadt (DE)

(72) Inventors: Nils SCHÄFER, Darmstadt (DE); Lambert ALFF, Darmstadt (DE); Márton MAJOR, Darmstadt (DE); Stefan PETZOLD, Frankfurt am Main (DE)

(73) Assignee: Technische Universität Darmstadt, Darmstadt (DE)

(21) Appl. No.: 17/910,824

(22) PCT Filed: Mar. 12, 2021
(86) PCT No.: PCT/EP2021/056396

§ 371 Date: Sep. 11, 2022

(30) Foreign Application Priority Data
Mar. 13, 2020 (DE) 10 2020 107 059.4

(51) Int. Cl. C23C 14/16; C23C 14/04; C23C 14/35; C23C 14/54

(52) U.S. Cl. CPC C23C 14/165; C23C 14/046; C23C 14/352; C23C 14/541; C23C 14/548

(57) ABSTRACT

In a method for coating a base body, a first target and a second target are arranged in a vacuum chamber. A base body to be coated is arranged in the vacuum chamber is heated to a coating temperature of less than 600° C. During sputtering with sputter gas ions, first target particles are liberated from the first target and second target particles are liberated from the second target and are deposited as coating particles on the base body. A first sputter rate is specified for the first target and a second sputter rate is specified for the second target such that, during the sputtering process, the coating is generated as an A15 phase with an intended stoichiometric ratio of the first target particles to the second target particles. A functional element has a base body and a coating of Nb₃Sn applied directly on the surface of the base body.

### TECHNICAL FIELD

The disclosure relates to a method for coating a base body with a coating of a first material and of a second material in a sputtering process.

### BACKGROUND

A number of different methods are known in practice with which an often comparatively thin coating can be produced on a base body. In a method described as sputtering, atoms from a solid described as the target are liberated by bombardment with energy-rich ions so that the liberated target atoms pass into the gas phase and are deposited on surfaces located in the vicinity. During a sputtering process, the base body to be coated is arranged close to a target so that the target atoms liberated from the target preferably are deposited to a surface of the base body and form the desired coating of the base body.

Functional elements, in which a base body has a coating that is composed of a combination of two or more starting materials, are known from numerous different application areas and required. A coating of this kind often cannot be produced by means of sputtering or can only be produced at a considerable cost. Such coatings are usually produced using other methods for this reason.

It is known that a group of substances of A15 phases is advantageously suitable for the production of superconductive functional elements. In the group of substances of A15 phases, two or three different metals usually form an intermetallic phase with an A15 structure. Some of the A15 phases have advantageous superconductive properties, so that these A15 phases are suitable for numerous application areas in which superconductive properties are advantageous or necessary. The A15 phases usually have a composition with a molecular formula A₃B, wherein A is a transition metal and B is a metal main group element of the periodic table. The component B can also be a mixture of different metal main group elements. A15 phases such as Nb₃Ge or Nb₃Sn, for example, facilitate the construction of superconductive magnets or cables with magnetic flux densities of more than 10T. From the field of superconductivity in particular, various considerations and experiments are known to produce a functional element having superconductive properties from a base body that is coated with a suitable coating of an A15 phase, such as Nb₃Sn, for example. For example, a superconductive cavity of a particle accelerator, which is usually produced from high-purity niobium, could thus be replaced by a functional element having a base body made of copper and a coating of Nb₃Sn. The base body can be manufactured from copper, for example. Such a functional element having a base body made of copper could be substantially cheaper than a corresponding functional element of high-purity niobium. The production of the coating of the base body from Nb₃Sn is expensive, however, and leads to limitations on the use of such a functional element.

It is known in practice that such a coating on a base body, for example made of copper, can be produced by a number of consecutive sputtering processes, wherein thin layers, for example of niobium and of tin, are applied alternately to the base body in succession by means of sputtering. Following this, the base body with the layer sequence of niobium and tin applied thereto must be heated, so that due to the heating of the layers caused thereby, diffusion of the individual atoms of the layers is brought about and the desired material Nb₃Sn is formed.

It has been shown, however, that the formation of Nb₃Sn requires heat treatment at high temperatures of roughly one thousand degrees Celsius and more, wherein even in advantageous method conditions, the coating arising therein is often formed inhomogeneously and furthermore different compounds and phases arise, so that the superconductive properties of the coating produced in this way are adversely affected. Furthermore, it can scarcely be prevented that atoms from the base body also diffuse into the coating during the heat treatment and are deposited in the coating. A diffusion of atoms from the base body into the coating can be reduced using a diffusion barrier of a suitable material, wherein the diffusion barrier is formed as a thin layer and is arranged between the base body and the coating of Nb₃Sn. This diffusion barrier usually impedes a removal of heat from the coating to the base body, however, which is advantageous or even necessary for many application areas, and thereby impairs the properties and usage possibilities of such a functional element.

### SUMMARY

A method for producing a coating of a base body with a coating of a first material and of a second material includes arranging a first target of the first material and a second target of the second material in a vacuum chamber. A base body to be coated is arranged in the vacuum chamber. A sputter gas is introduced into the vacuum chamber. During a sputtering process with sputter gas ions, first target particles are liberated from the first target and are deposited as coating particles on the base body, and second target particles are liberated from the second target and deposited as coating particles on the base body.

An object of the present disclosure is to configure the method for producing a coating of a base body with a coating such that a coating of two different metals can be produced economically and reliably with a crystal lattice that is as homogeneous as possible.

This object is achieved in that, during the sputtering process, a first sputter rate is specified for the first target and a second sputter rate is specified for the second target such that, during the sputtering process, the coating is generated with an intended stoichiometric ratio of the first target particles to the second target particles, and in that the base body is heated, during the sputtering process, by a heating device to a coating temperature of less than six hundred degrees Celsius. It has been shown that in a sputtering process in which the first target and the second target are simultaneously bombarded by the sputter gas ions and first target particles and second target particles are generated in a prescribed stoichiometric ratio, a comparatively homogeneous coating of the base body can be deposited on a surface of the base body.

The first target particles and the second target particles are deposited on the base body initially randomly at the respective location of impact on the surface of the base body. It has been shown that due to heating of the base body to a coating temperature of less than six hundred degrees Celsius, the first target particles and second target particles deposited on the surface of the base body have sufficient mobility due to the thermal energy to form the desired A15 phase and as a result to grow a homogeneous coating with a phase-pure crystal lattice on the base body. Since the first target particles and second target particles striking the base body are comparatively mobile on the surface, heating to less than six hundred degrees Celsius is sufficient to form the desired A15 phase from the first target particles and the second target particles on the surface. It is not necessary to subject the coated base body, during the sputtering process or following this, to heat treatment with heating to over one thousand degrees Celsius, as is necessary in a coating method already known in practice, in which thin layers of first target particles and then of second target particles are sputtered successively, which then combine with one another due to diffusion during the heat treatment and form the coating.

In heating of the base body during the sputtering process to less than six hundred degrees Celsius, the base body can consist of different materials, which are advantageous for different functional elements or application areas of the functional elements in question. An advantageous material of the base body for many application areas is copper, for example. When heating the base body made of copper to less than six hundred degrees Celsius, no appreciable diffusion of the copper material into the coating deposited on the surface of the base body takes place. It is therefore not necessary, when heating the base body to less than six hundred degrees Celsius, to arrange a diffusion barrier of a suitable material, with which the undesirable diffusion of copper into the coating can be reduced or where possible largely suppressed, between the base body and the coating applied thereto.

According to an advantageous configuration, it is provided that the first material is a first metal and that the second material is a second metal or a metal mix. The metal mix can contain two or more different metals, for example, which each combine with the first metal. In the formation of the desired crystal lattice of the coating, the respective compounds can then be combined with one another and combine according to the respective proportions into a homogeneous crystal lattice. If the second material is a second metal, it can be achieved by suitable specification of the method parameters that only a single combination of the first metal with the second metal occurs so that a phase-pure crystal lattice is formed.

It is preferably optionally provided that the first target particles from the first material and the second target particles from the second material form an A15 phase. In this case the material of the first target and the material of the second target can be selected such that first target particles and second target particles liberated from the first target and from the second target form an A15 phase, which has particularly advantageous properties for certain application areas. Depending on the first metal and the second metal or metal mix and the desired A15 phase that is to be formed from the metals, the first sputter rate and the second sputter rate are specified such that the stoichiometric ratio of first target particles to second target particles necessary for the formation of the A15 phase is specified. For many applications in which an intermetallic phase with an A15 structure of a type A3B is to be generated, a stoichiometric ratio of 75% to 25% is advantageous. It is consequently possible using the method to arrange a highly homogeneous and phase-pure coating of an A15 phase directly on a surface of a base body without a diffusion barrier having to be formed in between. Functional elements having a base body, for example made of copper or of a comparatively good heat-conducting material, can thus be provided with a superconductive coating so that the functional element produced in such a way can be used advantageously for numerous application instances on account of the superconductive properties of the coating.

According to one configuration, it can be provided that, during the sputtering process, at least one further, third target is arranged in the vacuum chamber, and in that for each further, third target a third sputter rate for the deposition of third target particles in the coating is specified such that the coating is generated with an intended stoichiometric ratio of the third target particles to the first and second target particles. Thus, instead of a second target with a metal mix, for example, a second target with a second metal and additionally a third target with a further, third material can be used, so that all three targets consist of pure metals or elements. An individual sputter rate can be specified for all three targets so that even complex stoichiometric ratios can be specified and achieved for the coating that is aimed for. In this way a coating can be produced, for example, in which Nb₃Sn and Nb₃Ge are combined to form a homogeneous crystal lattice.

It is preferably provided that the base body is heated, during the sputtering process, to a coating temperature of between two hundred degrees Celsius and six hundred degrees Celsius and particularly preferably to a coating temperature of between four hundred degrees Celsius and five hundred degrees Celsius. It has been shown that for many material combinations of two metals which form an A15 phase, a coating temperature of between two hundred degrees Celsius and six hundred degrees Celsius, or in many cases between four hundred degrees Celsius and five hundred degrees Celsius, is sufficient to enable the first target particles and second target particles striking the surface of the base body to have sufficient mobility to form the desired A15 phase with a phase-pure crystal lattice. Due to the necessary heating to a much lower coating temperature compared with other coating methods, in which different layers are sputtered consecutively, undesirable diffusion processes from the base body into the coating that gradually accumulates during the sputtering process or of individual components of the coating into the base body can be suppressed and if applicable avoided almost completely.

To improve the efficiency of the sputtering process, it is optionally provided that magnetron sputtering is carried out during the sputtering process. In this case an additional magnetic field is generated in the vicinity of the first target as well as in the vicinity of the second target in each case, due to which the electron density in a region is increased over the target surfaces provided for the liberation of target particles and on account of the ionisation of the sputter gas amplified thereby in this region, the sputter rate of the target material in question and thus the layer growth of the coating are increased. The options available for carrying out magnetron sputtering effectively and for optimising individual method parameters are known to a person skilled in the art.

According to an advantageous configuration of the method, it is optionally provided that the base body is treated in an adhesion-enhancing step preceding the sputtering process to amplify adhesion of the coating to a surface to be coated of the base body. The surface of the base body can be treated here chemically or physically, for example by an etching process or by irradiation with ion beams or with laser light. A region of the base body adjacent to the surface of the base body can be altered in this way or partially or completely removed. Chemical or physical properties of the surface can thereby be changed such that the coating subsequently applied adheres much more strongly to the surface. It is likewise possible to apply a bonding layer strengthening the bonding effect to the surface of the base body. The bonding layer can act as a bonding agent. Here the base body can also be cooled during the adhesion-enhancing step or heated to an adhesion step temperature that corresponds to the coating temperature or is lower but increased compared with room temperature. If applicable, the surface of a base body provided for the coating can be changed with the adhesion-enhancing step such that a coating becomes possible in the first place.

Simple control of the individual components that are used and operated during a sputtering process to carry out the method can be achieved according to a configuration of the inventive idea in that a specified sputter performance ratio is specified for the first sputter rate and the second sputter rate. The sputter performance ratio can be determined in advance, for example, by separate investigations depending on the target materials used. The sputter performance ratio as a ratio of the first sputter rate to the second sputter rate can also be determined in advance depending on the coating temperature specified in an individual case and specified for carrying out the sputtering process. Due to the specification of a sputter performance ratio that is kept constant during a sputtering process, the first sputter rate and the second sputter rate can be varied during a coating process in order, for example, to accelerate or retard the layer growth depending on the increasing distance from the surface of the base body, wherein due to the fixedly specified sputter performance ratio, the stoichiometric ratio of the first target particles relative to the second target particles is kept constant and homogeneous formation of an A15 phase with a phase-pure crystal lattice is supported.

According to a particularly advantageous configuration, it is provided that the first metal is niobium and the second metal is tin or a mixture of two or more elements with more than 50 mole percent of tin. Due to the combination of niobium and tin, an intermetallic chemical compound and particularly advantageously even the A15 phase Nb₃Sn can be generated during the coating process. The coating material Nb₃Sn produced in such a way has extremely advantageous superconductive properties and is also suitable for applications that call for large currents and magnetic fields, such as is the case of particle accelerators, for example.

It can be appropriate for certain applications that instead of a combination of exclusively niobium and tin, or instead of an A15 phase Nb₃Sn, a coating is generated of niobium on the one hand and a mixture of tin and another element such as gallium or aluminium, for example, on the other hand. The respective proportions can be specified by the mixture used for the second material such that a coating is formed with advantageous properties.

It is likewise possible, in place of two targets made of a first metal and of a second metal mix, which are sputtered simultaneously during the sputtering process, to provide three targets, the material of which consists of a first metal, a second metal and a third metal, which are sputtered simultaneously. In this case the stoichiometric ratio of the three different metals in the resulting coating can be specified via the respective sputter rates such that the desired coating material arises.

It has been shown that a particularly effective formation of the A15 phase Nb₃Sn with a phase-pure crystal lattice is supported in that the sputter rate of niobium corresponds to 5.25 times the sputter rate of tin. At a coating temperature of around four hundred and fifty degrees Celsius in particular, a particularly homogeneous coating of Nb₃Sn can be generated with this sputter performance ratio. For other combinations of target materials, a sputter performance ratio different from this can be determined and specified if applicable depending on the desired coating temperature.

It has further been shown that for functional elements that have superconductive properties and are provided and suitable for use in particle accelerators, for example, a previously described coating with a layer thickness of between 200 nm and 5 μm is advantageous. The layer thickness can be specified precisely with the described sputtering process depending on the requirements in each case.

It is likewise conceivable that according to a configuration, the coating is produced with a layer sequence of at least two layers of a coating material, wherein arranged between adjacent layers of a superconductive coating material is a separating layer of another, non-superconductive material in each case. Two layers of the coating material can be separated from one another by the separating layer in order to enable or amplify particularly advantageous properties of the coating by such a layer sequence. In this case the electrical conduction properties that are relevant in practice can be improved in particular by a sequence of two or more thin layers of a superconductive coating material separated from one another by a separating layer of a non-superconductive material, and the use of the base body coated in such a way as a functional element in particle accelerators or in superconductive cables, for example, can be facilitated or supported thereby.

The separating layer can consist of an insulator material such as plastic, for example, and be applied using customary coating methods to a layer of a superconductive coating material, which was applied for its part by sputtering. It is likewise conceivable that the separating layer is produced from an electrically conductive material such as from a metal or metal compound, for example, but which has no superconductive properties at least in conditions in which the coating material has superconductive properties. A separating layer of a metal material can likewise be applied by a sputtering process. A separating layer of a metal material usually has a high heat-conducting capacity, whereby a highly advantageous thermal conductivity of the coated base body can be achieved in some applications. High-melting metals such as tantalum, molybdenum or tungsten, for example, are regarded here as advantageous materials for a separating layer also on account of the high thermal conductivity. It is also conceivable that the material of the separating layer matches the material that the base body consists of.

According to a configuration that is considered particularly advantageous, it is provided that a ceramic layer and preferably a layer of aluminium nitride ceramic is applied as a separating layer. Aluminium nitride ceramic has particularly high thermal conductivity and is poorly electrically conductive in contrast to metals. A layer of aluminium nitride ceramic can likewise be applied by a sputtering process to a base body previously coated with a superconductive coating material. Since only the targets have to be exchanged for this purpose, a coating consisting of a plurality of layers, with a plurality of layers of superconductive coating material and with one or more layers of aluminium nitride ceramic, can be produced virtually without interruption and without greater changeover times using the sputtering method. By coating a base body with a coating of this kind, functional elements with particularly advantageous superconductive properties in combination with very high thermal conductivity can be facilitated and produced in the area of superconductive coating and in the base body.

For the production of various functional elements with a recess or with a hollow space, it is advantageous or even necessary that an inner wall of the recess or of the hollow space is provided with a coating. According to a particularly advantageous configuration, it is therefore provided that the first target and the second target are arranged in a recess or in a hollow space, accessible from outside, of a base body and that an inner wall of the base body delimiting the recess or the hollow space is coated in the sputtering process. Since the inner wall of the recess or hollow space to be coated encloses the targets, virtually all target particles liberated from the targets in the sputtering process are deposited on the inner surface to be coated of the base body and form the intended coating. The sputtering process can be carried out particularly effectively and economically due to this.

Furthermore, it can be provided optionally that the base body on the one hand and the first and second target on the other hand can be displaced relative to one another during the sputtering process. For example, the base body enclosing the targets can thus be set in a rotational movement while the sputtering process is carried out. It is likewise conceivable for the targets to be fixed on a rotatable or movably supported target holder and for the target holder to be displaced relative to the base body. It is likewise possible, furthermore, that both the base body and the targets are displaced simultaneously in order to be able to realise complex movement sequences relative to one another as simply as possible, for example. A very short method duration for the sputtering process and a highly uniform formation of the sputtered coating can be enabled thereby. Regions of the inner wall of the recess or of the hollow space that are not envisaged for coating can be covered before carrying out the sputtering process.

The disclosure also relates to a functional element having a base body with a coating of an A15 phase. Numerous different application areas are known in practice in which a functional element can have a base body and a coating applied thereto of an A15 phase, such as Nb₃Sn, for example. Such a functional element could be used as a replacement for a functional element, for example, which is produced entirely from a uniform but cost-intensive material. A practical example of such a functional element is a cavity of a particle accelerator. Such cavities are usually produced from high-purity niobium, whereby high material and manufacturing costs arise. It has been shown that for many applications and in particular for cavities of a particle accelerator, functional elements are also suitable in which a base body with a coating of a superconductive A15 phase and in particular with a Nb₃Sn coating are suitable. The production methods known hitherto for such functional elements are cost-intensive and consequently unsatisfactory, however.

It is therefore regarded as another object of the disclosure to configure a functional element such that it can be produced economically and has properties suitable for use as a cavity in a particle accelerator, for example.

This object is achieved in that the coating is produced directly on a surface of the base body using a previously described sputtering method. Due to the use of the sputtering method according to the disclosure, the arrangement of a diffusion barrier between the base body and the coating can be eliminated. A suitable diffusion barrier not only has the desired property of preventing the undesirable diffusion of particles from the base body into the coating during the production of the coating or during any heat treatment that may subsequently be necessary, but also constitutes a comparatively effective but undesirable barrier to heat transportation during the intended use of the functional element. By dispensing with such a diffusion barrier, a heat exchange between the coating and the base body is improved and the suitability of such a functional element for various application areas is thereby improved.

According to an advantageous configuration, it is provided that the base body is made of copper. Copper is a comparatively inexpensive material that has a high electrical conductivity as well as high thermal conductivity, which is advantageous for many application areas of such functional elements. Copper can also be processed in a simple manner so that economical production of the base body is supported even in the case of complex designs.

For many application areas, for example in connection with particle accelerators or with superconductive motors or generators, it can be advantageous for the inner wall of a recess or hollow space in the base body to be coated with a superconductive coating. It is optionally provided therefore that the coating partially or completely covers an inner wall of a recess or hollow space of the base body.

According to a particularly advantageous configuration, it is provided that the functional element is a cavity for an accelerator. A cavity that can be used as a functional element in a particle accelerator usually has a rotationally symmetrical design with a continuous hollow space. This hollow space can be coated with an superconductive coating. Such a cavity can be produced particularly economically and has the superconductive or electrically conductive and heat-conducting properties required for use in a particle accelerator.

Another and likewise advantageous utilisation possibility for coated base bodies relates to superconductive motors or generators, wherein the functional element can be a superconductive cable or a superconductive conduction element for solenoids. Copper foils or copper strips, for example, can thus be provided with a coating, for example of Nb₃Sn with superconductive properties, in order then to be used as superconductive solenoids in highly efficiently utilisable superconductive motors or generators.

The copper foils or copper strips or corresponding functional elements having a base body made of another suitable material can be shaped into the desired shape using normal methods. The superconductive coating can be applied easily using the sputtering method according to the disclosure.

Exemplary embodiments of the inventive idea are explained in greater detail below and depicted schematically in the drawing.

### BRIEF DESCRIPTION OF THE DRAWINGS

FIG. 1 shows a schematic layout of a device with which the method for producing a coating can be carried out.

FIG. 2 shows a schematic representation of measurement results of X-ray diffractometry measurement of a coating produced at a coating temperature of four hundred and thirty-five degrees Celsius with Nb₃Sn, wherein the intensity of the scattered X-ray radiation is depicted over the diffraction angle 2-theta.

FIG. 3 shows measured values of the electrical resistance of the coating measured in FIG. 2 in a temperature range between twelve degrees Kelvin and twenty degrees Kelvin, standardised to the electrical resistance at twenty degrees Kelvin.

FIG. 4 shows a schematic representation of a partial region of a functional element having a base body and a coating arranged directly on a surface of the base body.

FIG. 5 shows a schematic sectional view of a partial region of the coated base body as in FIG. 4, wherein a region of the base body adjacent to the surface was treated and changed in an adhesion-enhancing step in order to increase the bonding effect for the coating applied thereto.

FIG. 6 shows a schematic sectional view of a partial region of the coated base body as in FIGS. 4 and 5, wherein the coating consists of a layer sequence.

FIG. 7 shows a schematic sectional view through a hollow space of a base body in which two targets are arranged during carrying out of the sputtering process.

### DETAILED DESCRIPTION

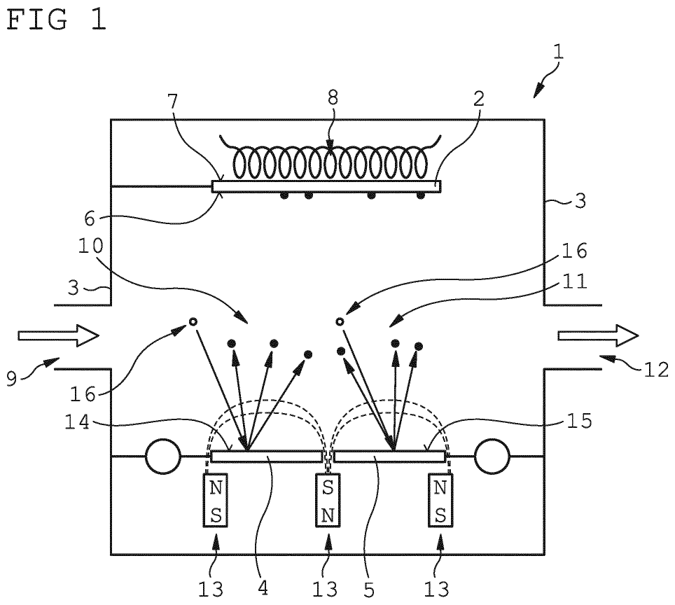

In FIG. 1, a device 1 is depicted by way of example with which a method for coating a base body 2 with a coating of an A15 phase can be carried out. In a coating chamber 3, in which a vacuum can be created, a first target 4 made of a first target material and a second target 5 made of a second target material are arranged adjacent to one another. The target material of the first target 4 is a first metal, namely niobium (Nb). The target material of the second target 5 is a second metal, namely tin (Sn).

Arranged opposite the two targets 4, 5 is the base body 2 made of copper, wherein a surface 6 of the base body 2 facing the two targets 4, 5 is to be coated. The base body 2 can be heated during a sputtering process from a rear side 7 by a heating device 8 to a specifiable coating temperature. In the exemplary embodiments reproduced below, the coating temperature specified for the coating process in question is 435° C.

The coating chamber 3 has an inlet 9 for a suitable sputter gas, which can be a noble gas, for example, and preferably argon. The sputter gas can already have been ionised in advance or can be ionised in the coating chamber 3. The two targets 4, 5 and the base body 2 can each be brought to an individually specifiable electric potential so that an electrical field is formed in the coating chamber 3 that accelerates positively charged sputter gas ions 16 in the direction of the two targets 4, 5. By specification of a sufficiently high potential difference, the sputter gas ions 16 can be accelerated sufficiently on the way to the first target 4 or to the second target 5 to liberate first target particles 10 when they strike the first target 4 and to liberate second target particles 11 when they strike the second target 5. By suitable specification of the respective electric potentials and thus of the potential differences that the sputter gas ions 16 pass through on the way to the first and second target 4, 5, the respective sputter rates of the first target 4 and the second target 5 can be influenced and specified. The first and second target particles 10, 11 liberated by the bombardment with sputter gas ions 16 are deposited inter alia on the surface 6 of the base body 2. Sputter gas ions 16, used sputter gas particles or target particles 10, 11 which were liberated from the first target 4 or from the second target 5 and not deposited on a surface can be removed from the coating chamber 3 through an outlet 12.

Using a suitable magnetic field generating device 13, a magnetic field is generated respectively in a region between the two targets 4, 5 and the base body 2 in the immediate environment of the two targets 4, 5, due to which field free electrons are concentrated in a region over a respective surface 14, 15 of the two targets 4, 5. The density of the sputter gas ions 16 striking the respective target 4, 5 and thus the sputter rates for the first target 4 and for the second target 5 can be influenced thereby.

The first target particles 10 liberated from the first target 4 and second target particles 11 liberated from the second target 5 by the sputter gas ions 16 are deposited on the surface 6 of the base body 2 heated by the heating device 8. Due to the thermal energy of the heated base body 2, sufficient energy is transmitted to the target particles 10, 11 being deposited so that these migrate along the surface 6 and can react to give the desired A15 phase. In the exemplary embodiment depicted as an example, the first target particles 10 of niobium deposited on the surface 6 react with the second target particles 11 of tin to form the intermetallic phase Nb₃Sn. In this case a highly homogeneous coating with a phase-pure crystal lattice is generated.

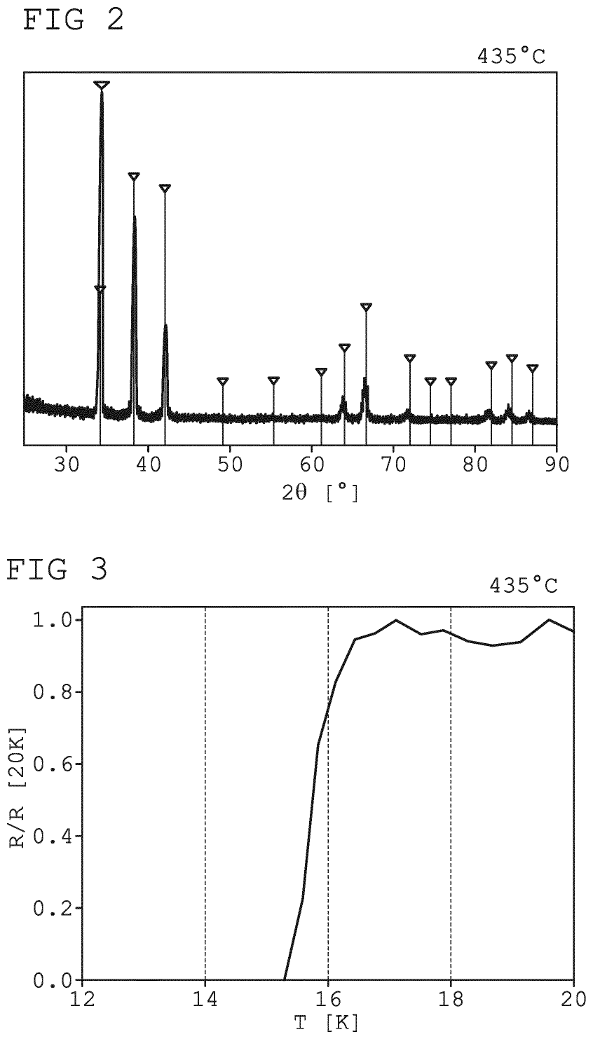

FIG. 2 depicts the measurement result of X-ray diffractometry measurement of a coating of Nb₃Sn produced using the method described previously in the device 1 depicted as an example. Here the intensity I of the X-ray radiation scattered on the coating is depicted in an arbitrary unit as a function of the respective diffraction angle 2θ over a range of the diffraction angle 2θ between 30° and 90°. Exclusively characteristic diffraction peaks of Nb₃Sn could be detected by the measurement, which peaks occurred at the diffraction angles 2θ indicated in each case by a dashed line with a concluding triangle. Other likewise possible compounds of niobium and tin such as NbSn₂ or Nb₂Sn₅, for example, could not be detected, on the other hand, likewise pure niobium or pure tin. The measurement result accordingly confirms that the desired coating of the base body 2 with the superconductive material Nb₃Sn with a highly phase-pure crystal lattice could be generated using the method according to the disclosure.

In FIG. 3, the electrical resistance R for the coating of Nb₃Sn measured in FIG. 2 by X-ray diffractometry is shown as a function of the temperature T, wherein the electrical resistance R is standardised to the measured resistance value R(20K) at a temperature T of 20 K. It appears that the coating has superconductive properties and an infinitesimally low standardised resistance R/R (20K) at a temperature T of below roughly 15.3 K. The transition temperature above which the superconductive property disappears is roughly 16.3 K and is close to the highest transition temperature of 18.3 K for this coating material that has ever been established for a bulk material or for a solid with comparatively large dimensions. This measurement also proves that a high-quality coating of Nb₃Sn with a phase-pure crystal lattice could be produced using the method according to the disclosure.

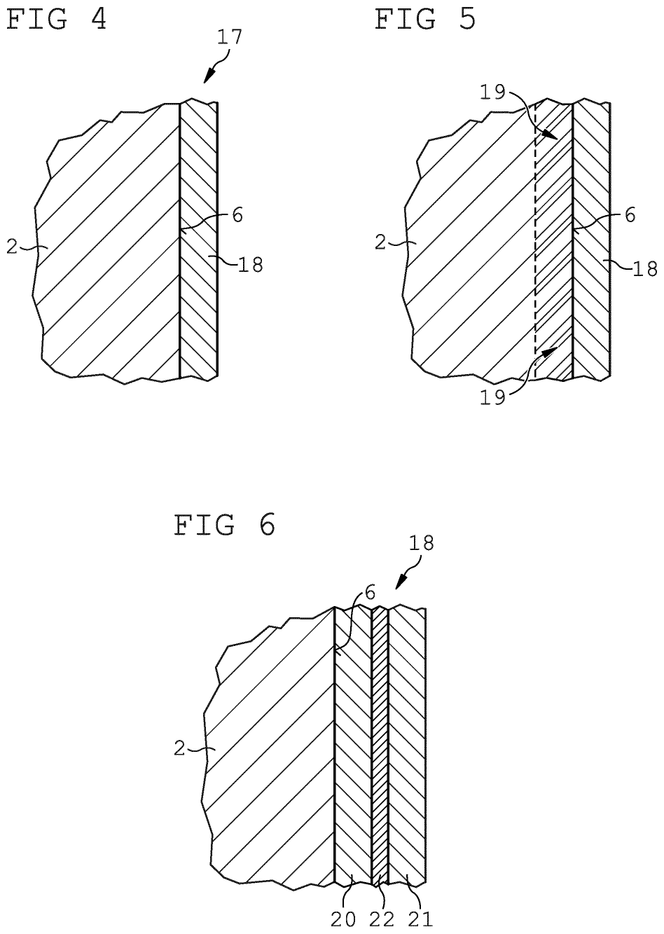

A section of a functional element 17 is depicted by way of example in FIG. 4. A coating 18 of Nb₃Sn is applied directly on the surface 6 of the base body 2, which consists of copper in the exemplary embodiment shown. In contrast to the functional elements with such a coating that are produced using conventional methods, no separate diffusion barrier is arranged between the surface 6 of the base body 2 and the coating 18. Highly effective heat transmission from the base body 2 into the coating 18 and vice versa is supported thereby, which is advantageous for numerous applications of such functional elements 17.

In the exemplary embodiment depicted in FIG. 5, the surface 6 to be coated of the base body 2 was treated by an etching process in an adhesion-enhancing step preceding the sputtering process and a region 19 of the base body 2 adjacent to the surface 6 was changed such that the coating 18 subsequently applied to the surface 6 adheres more strongly.

In the exemplary embodiment depicted in FIG. 6, the coating 18 has a layer sequence consisting of two layers 20, 21 of a superconductive coating material, between which layers a separating layer 22 of a non-superconductive metal is arranged. The two layers 20, 21 have each been applied using the sputtering method. The separating layer 22 can likewise be applied using a sputtering method or also using any conventional coating method. Here the surfaces lying externally in each case and then covered by a layer 20, 21, 22 applied thereto can each be treated in an adhesion-enhancing step and the bonding effect for the subsequently applied layer 20, 21, 22 improved thereby.

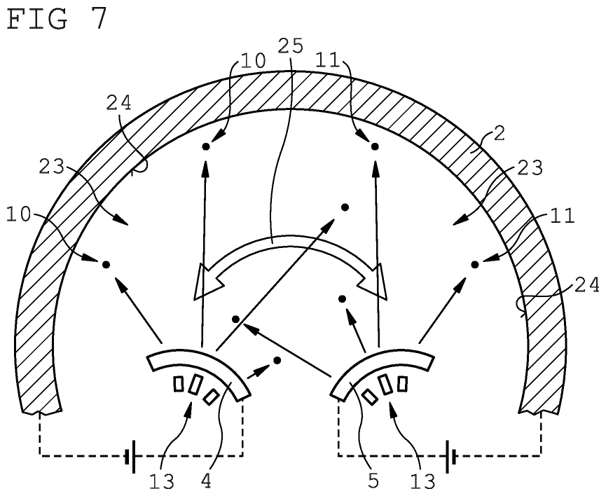

In FIG. 7, an exemplary embodiment of a base body 2 with a hollow space 23 is depicted merely schematically, wherein an inner wall 24 of the hollow space 23 in the base body 2 is provided with the coating 18 during the sputtering process. For this purpose, the first target 4 and the second target 5 as well as the associated components of the magnetic field generating device 13 are arranged in the hollow space 23 of the base body 2 during the sputtering process. In addition, a relative movement, indicated only by way of example by an arrow 25, between the base body 2 and the first and second target 4, 5 arranged in the hollow space 23 of the base body 2 can be brought about during the sputtering process. Thus the base body 2, for example, can rotate about the first and second target 4, 5, which are fixed stationarily in each case on a target holder, which is not shown and which projects into the hollow space 23 of the base body 2, in order to generate as quickly as possible a coating 18 of the inner wall 24 of the hollow space 23 in the base body 2 that is as uniform as possible.

1.-19. (canceled)

20. A method for coating a base body (2) with a coating (18) of a first material and of a second material, comprising:
arranging a first target (4) made of the first material and a second target (5) made of the second material in a vacuum chamber;
arranging the base body (2) to be coated in the vacuum chamber;
introducing a sputter gas into the vacuum chamber;
liberating, during a sputtering process with sputter gas ions (16), first target particles (10) from the first target (4) and depositing the first target particles (10) as coating particles on the base body (2);
liberating second target particles (11) from the second target (5) and depositing the second target particles (11) as coating particles on the base body (2);
specifying, during the sputtering process, a first sputter rate for the first target (4) and specifying a second sputter rate for the second target (5) such that, during the sputtering process, the coating (18) is generated with an intended stoichiometric ratio of the first target particles (10) to the second target particles (11); and
heating the base body (2), during the sputtering process, by a heating device (8) to a coating temperature of less than 600° C.

21. The method according to claim 20,
wherein the first material is a first metal and that the second material is a second metal or a metal mix.

22. The method according to claim 20,
wherein the first target particles (10) of the first material and the second target particles (11) of the second material form an A15 phase.

23. The method according to claim 20,
wherein, during the sputtering process, at least one further, third target is arranged in the vacuum chamber, and
wherein for each further, third target a third sputter rate for the deposition of third target particles in the coating is specified such that the coating is generated with an intended stoichiometric ratio of the third target particles to the first and second target particles (10, 11).

24. The method according to claim 20,
wherein the base body (2) is heated, during the sputtering process, to a coating temperature of between 400° C. and 500° C.

25. The method according to claim 20,
wherein magnetron sputtering is carried out during the sputtering process.

26. The method according to claim 20,
wherein the base body (2) is treated in an adhesion-enhancing step preceding the sputtering process in order to strengthen adhesion of the coating (18) to a surface (6) of the base body (2) to be coated.

27. The method according to claim 20,
wherein a specified sputter performance ratio is specified for the first sputter rate and the second sputter rate.

28. The method according to claim 20,
wherein the first material is niobium and the second material is tin or a mixture of two or more elements with more than 50 mole percent of tin.

29. The method according to claim 28,
wherein the sputter rate of niobium corresponds to 5.25 times the sputter rate of the second material.

30. The method according to claim 20,
wherein the coating (18) is produced with a layer sequence of at least two layers (20, 21) of a coating material,
wherein arranged between adjacent layers (20, 21) of a superconductive coating material in each case is a separating layer (22) of another, non-superconductive material.

31. The method according to claim 30,
wherein a ceramic layer is applied as a separating layer (22).

32. The method according to claim 20,
wherein the first target (4) and the second target (5) are arranged in a recess or in a hollow space (23) of the base body (2) that is accessible from outside and
wherein an inner wall (24) of the base body (2) delimiting the recess or the hollow space (23) is coated in the sputtering process.

33. The method according to claim 32,
wherein the base body (2) on the one hand and the first and second target (4, 5) on the other hand are displaced relative to one another during the sputtering process.

34. A functional element (17) having a base body (2) with a coating (18) of an A15 phase,
wherein the coating (18) is produced directly on a surface (6) of the base body (2) using the method according to claim 20.

35. The functional element (17) according to claim 34,
wherein the base body (2) is made of copper.

36. The functional element (17) according to claim 34,
wherein the base body (2) has a recess or a hollow space (23) and the coating (18) covers an inner wall (24) of the recess or the hollow space (23) partially or completely.

37. The functional element (17) according to claim 34,
wherein the functional element (17) is a cavity for an accelerator.

38. The functional element (17) according to claim 34,
wherein the functional element (17) is a superconductive cable or a superconductive conduction element for solenoids.
